(19) United States
(12) Patent Application Publication
(10) Pub. No.: US 2016/0334719 A1
(43) Pub. Date: Nov. 17, 2016

(54) SUBASSEMBLY OF AN OPTICAL SYSTEM, IN PARTICULAR IN A MICROLITHOGRAPHIC PROJECTION EXPOSURE APPARATUS

(71) Applicant: Carl Zeiss SMT GmbH, OBERKOCHEN (DE)

(72) Inventors: Tilman Schwertner, Schriesheim (DE); Stacy Figueredo, Munchen (DE)

(21) Appl. No.: 15/218,499

(22) Filed: Jul. 25, 2016

Related U.S. Application Data
(63) Continuation of application No. PCT/EP2015/052825, filed on Feb. 11, 2015.

(30) Foreign Application Priority Data
Feb. 21, 2014 (DE) 102014203144.3

(51) Int. Cl. G03F 7/20

(52) U.S. Cl. CPC G03F 7/70891

(57) ABSTRACT

The disclosure provides a subassembly of an optical system, in particular in a microlithographic projection exposure apparatus, with an element and at least one temperature-controlling device for controlling the temperature of this element. The temperature-controlling device has a cooling medium in a closed circuit with at least one tube-like portion. The cooling medium is transportable away from the element or to the element in the tube-like portion while performing a two-phase transition. A heating device is provided for interrupting the transport of the cooling medium by heating up the cooling medium.

### CROSS-REFERENCE TO RELATED APPLICATIONS

The present application is a continuation of, and claims benefit under 35 USC 120 to, international application PCT/EP2015/052825, filed Feb. 11, 2015, which claims benefit under 35 USC 119 of German Application No. 10 2014 203 144.3, filed Feb. 21, 2014. The content of these applications are hereby incorporated by reference.

### FIELD

The disclosure concerns a subassembly of an optical system, in particular in a microlithographic projection exposure apparatus.

### BACKGROUND

Microlithography is used for the production of microstructured components, such as for example integrated circuits or LCDs. The microlithographic process is carried out in what is known as a projection exposure apparatus, which has an illumination device and a projection lens. The image of a mask (=reticle) illuminated via the illumination device is thereby projected via the projection lens onto a substrate (for example a silicon wafer) that is coated with a light-sensitive layer (photoresist) and is arranged in the image plane of the projection lens, in order to transfer the mask structure to the light-sensitive coating of the substrate.

In projection lenses designed for the EUV range, i.e. at wavelengths of, for example, approximately 13 nm or approximately 7 nm, mirrors are used as optical components for the imaging process because of the lack of availability of suitable light-transmissive refractive materials.

A problem that arises in practice is that, in particular as a result of absorption of the radiation emitted by the EUV light source, the EUV mirrors undergo heating and an accompanying thermal expansion or deformation, which in turn may have the consequence of impairing the imaging properties of the optical system.

In the illumination device of a microlithographic projection exposure apparatus designed for operation in EUV, the use of facet mirrors in the form of field facet mirrors and pupil facet mirrors as focusing components is known in particular, for example from DE 10 2008 009 600 A1. Such facet mirrors are made up of a multiplicity of individual mirrors or mirror facets that can be respectively designed to be tiltable via flexures for the purpose of adjustment or else for realizing certain distributions of the illumination angle. These mirror facets may in turn for their part include a plurality of micro-mirrors. Furthermore, it is also known, for example from WO 2005/026843 A2, to use mirror arrangements which include a multiplicity of mirror elements that can be set independently of one another in an illumination device of a microlithographic projection exposure apparatus designed for operation at wavelengths in the VUV range for the setting of defined illumination settings (i.e. intensity distributions in a pupil plane of the illumination device).

In particular in the case of such mirror arrangements including a plurality of mirror elements, the dissipation of the thermal loads mentioned at the beginning represents a demanding challenge, primarily because of the comparatively confined installation spaces and the relatively high thermal loads occurring at the individual mirror elements. Thus, for instance when removing the thermal loads of flexibly mounted and actuable mirror elements, one of the reasons why this heat removal is found to be difficult is that the comparatively small cross sections of flexures used for the high-precision positioning or actuation, such as for example flexible leaf springs, only allow relatively poor heat dissipation to the surrounding structure.

In other words, in a mirror arrangement with mirror elements that are adjustable in at least one degree of freedom (for example tiltable about at least one tilting axis), combining the flexible adjustability with effective removal of the thermal loads occurring on the mirror elements during the operation of the optical system is something that particularly presents a demanding challenge. This problem is further exacerbated in the operation of a microlithographic projection exposure apparatus by the fact that the typically encountered vacuum conditions (and possibly an existing inert gas atmosphere) have the consequence that the proportion of heat radiation in the form of convection is typically negligible, so that essentially only the process of heat conduction is available for the removal of the thermal loads.

Apart from the heat removal discussed above, when operating a microlithographic projection exposure apparatus there is also the need possibly to implement a specifically achieved temperature control in such a way that one or more mirror elements can also be set to a temperature that is higher in comparison with the surroundings. This may be desirable for example in order to set what is known as the “zero-crossing temperature” in the region of the optically effective surface of a mirror element. At this “zero-crossing temperature”, the coefficient of thermal expansion has a zero crossing in its temperature dependence, around which no thermal expansion, or only negligible thermal expansion, of the mirror substrate material takes place. So, if for example this “zero-crossing temperature” has a value that exceeds the general system temperature or the temperature of the surroundings of the mirror element concerned, instead of just “cooling” the mirror element, a temperature control of the kind described above may also be desirable.

As prior art, reference is made, only by way of example, to DE 10 2012 200 733 A1, DE 10 2004 046 764 A1, U.S. Pat. No. 8,188,595 B2, U.S. Pat. No. 4,467,861 and US 2003/0192669 A1.

### SUMMARY

Against the above background, the present disclosure seeks to provide a subassembly of an optical system, in particular in a microlithographic projection exposure apparatus, that allows improved temperature control of at least one element on which electromagnetic radiation impinges during the operation of the optical system.

According to one aspect of the disclosure, the disclosure concerns a subassembly of an optical system, in particular in a microlithographic projection exposure apparatus, with an element and at least one temperature-controlling device for controlling the temperature of the element. The temperature-controlling device having a cooling medium in a closed circuit with at least one tube-like portion. The cooling medium is transportable away from the element or to the element in the tube-like portion while performing a two-phase transition. A heating device is provided for interrupting the transport of the cooling medium by heating up the cooling medium.

The disclosure is based in particular on the concept of taking as a basis a structure with a cooling medium that can be transported in a closed circuit while performing a two-phase transition (for example, as described in still more detail hereinafter, in what is known as a heat pipe) and implementing a control of the temperature of an element (for example an optical element such as for instance a mirror element) in such a way that an interruption (that is to say as it were a “switching off” of the circuit or of the heat pipe) can be brought about via a heating device.

The transport of the cooling medium may take place for example by using capillary action, by using a steady or unsteady flow as a result of a differential pressure brought about by convection between a liquid phase and a gaseous phase, or else by using a liquid differential pressure brought about by convection inside a vapour chamber, it also being possible for the aforementioned differential pressures to be used in combination with gravitational differential pressures. Furthermore, the aforementioned differential pressures may be implemented in a passive form (i.e. without requiring a pump) or in an active form (i.e. using a pump). Furthermore, a combination is also possible, for instance by providing a pump that operates in a further or secondary closed circuit, while a heat exchange takes place between this circuit and a passive circuit (which is arranged alongside or under the element).

In this case, the disclosure is not restricted to the closed cooling medium circuit being implemented in the form of a heat pipe, but rather it can be used in conjunction with all heat transporting systems that include a two-phase transition (for example also the two-phase thermosiphon that is likewise explained in still more detail hereinafter). These systems are in each case based on the functional principle known per se that a liquid cooling medium present in the closed circuit (that is to say for example the heat pipe) changes into the gaseous state when heated and changes back again into the liquid state when cooled.

Taking the functional principle described above as a basis, the disclosure thus exploits the fact that the temperature gradient existing within the closed circuit can be changed in a specific manner via the heating device used according to the disclosure. This can take place in particular for instance by providing that heating up the cooling medium between the element and a cooler has the effect of creating a situation in which there is between the heating-up region and the cooler a temperature gradient relevant for the transporting of the cooling medium or the two-phase transition (whereas, in the direction of the circuit, the optical element essentially no longer “sees” the temperature of the cooler but instead the temperature corresponding to the region heated up by the heating device). As far as the element is concerned, such a configuration is then synonymous with “switching off” the circuit or the heat pipe, with the consequence that this optical element can correspondingly heat up on account of the thermal load acting during the operation of the optical system.

Furthermore, by heating up the cooling medium, it is also possible via the heating device to set up a configuration in which the cooling medium in the entire circuit is in the gas phase. Such a configuration has the consequence that the functionality of the two-phase heat transporting system concerned (for example the heat pipe) is completely switched off, and consequently any heat transfer is restricted solely to the effect of the heat conduction by the gas concerned or the (pipe) wall surrounding this gas.

The heating device according to the disclosure may be configured in particular as an electrical heating device (preferably that can be switched on and off).

According to one embodiment, the ratio between the length and the outside diameter of this tube-like portion is at least 5:1, more particularly at least 10:1.

According to one embodiment, the tube-like portion of the temperature-controlling device according to the disclosure is elastically deformable. In particular, the ratio between the length and the outside diameter of this tube-like portion may be at least 50:1, more particularly at least 80:1.

As a result of the elastic deformability of the tube-like portion achieved according to this further approach (in particular on account of the tubular portion or the heat pipe being made to have a small outside diameter in relation to the length), a significant reduction in the stiffness, and consequently the undesired influence of parasitic forces, can be achieved, with the consequence that it is possible throughout the lifetime of the optical system to achieve an elastic deformation while avoiding or reducing the introduction of vibrations (for example from a connected cooling system). As a result, the temperature control described above, made possible according to the disclosure, for example of the adjustable mirror elements of a mirror arrangement such as a facet mirror, can thus be combined with implementation of the mobility for this adjustability.

The last-described aspect of the flexible configuration of the two-phase heat transporting system according to the disclosure (for example the heat pipe) is also advantageous independently of the concept of the heating device or the switching off of the two-phase heat transporting system or the heat pipe that is made possible as a result. Therefore, according to a further aspect, the disclosure also concerns a subassembly of an optical system, in particular in a microlithographic projection exposure apparatus, with an element and at least one temperature-controlling device for controlling the temperature of this element. The temperature-controlling device has a cooling medium in a closed circuit with at least one tube-like portion, this cooling medium being transportable away from the element or to the optical element in the tube-like portion while performing a two-phase transition. The tube-like portion is elastically deformable.

Furthermore, the disclosure also relates to a subassembly of an optical system, in particular in a microlithographic projection exposure apparatus, with an element and at least one temperature-controlling device for controlling the temperature of this element. The temperature-controlling device has a cooling medium in a closed circuit with at least one tube-like portion. The cooling medium is transportable away from the element or to the element in the tube-like portion while performing a two-phase transition. A ratio between the length and the outside diameter of the tube-like portion being at least 50:1.

According to one embodiment, the subassembly has at least one flexure, which allows a tilting of the element about at least one tilting axis.

According to one embodiment, this flexure is formed in the tube-like portion. In this way the kinematics for implementing the adjustability (for example tilting) of the element can be integrated into the tube-like portion that is present for the formation of the closed circuit. However, the disclosure is not restricted to this. Thus, in further embodiments, the kinematics for implementing the adjustability of the element may also be provided independently of or in addition to the tube-like portion, with the consequence that the kinematics concerned can then be designed without having to undertake an additional thermal functionality.

According to one embodiment, the tube-like portion has a varying cross section.

According to one embodiment, furthermore, a pumping device is provided for manipulating the cooling medium pressure existing within the circuit. This makes it possible to achieve beyond the mere switching on and off of the two-phase heat transporting system (for example the heat pipe) a continuous setting of the functionality of the two-phase heat transporting system, or of the heat transport brought about by it. However, the disclosure is not restricted to an “actively pumped” system, so that even systems without a pumping device or with a passive flow are covered by the disclosure.

According to one embodiment, the temperature-controlling device is configured as a heat pipe.

According to one embodiment, the temperature-controlling device is configured as a two-phase thermosiphon.

According to one embodiment, the element is a reflective optical element. In further embodiments, the element may also be a collector mirror of an EUV light source or a microlithographic mask.

In particular, the element may be a mirror element of a mirror arrangement including a plurality of mirror elements that are adjustable independently of one another.

According to one embodiment, this mirror arrangement is a facet mirror, in particular a field facet mirror or a pupil facet mirror.

According to one embodiment, the element is designed for an operating wavelength of less than 30 nm, in particular less than 15 nm.

The disclosure also concerns an optical system of a microlithographic projection exposure apparatus, in particular an illumination device or a projection lens, with a subassembly with the features described above, and also concerns a microlithographic projection exposure apparatus with such an optical system.

Further configurations of the disclosure can be taken from the description and the subclaims.

### BRIEF DESCRIPTION OF THE DRAWINGS

The disclosure is explained in more detail below on the basis of exemplary embodiments that are represented in the accompanying figures, in which:

FIGS. 1-7 show schematic representations for explaining the structure of a subassembly according to the disclosure in various embodiments of the disclosure; and

FIG. 8 shows a schematic representation of a microlithographic projection exposure apparatus designed for operation in EUV, in which the disclosure can be realized for example.

### DETAILED DESCRIPTION OF PREFERRED EMBODIMENTS

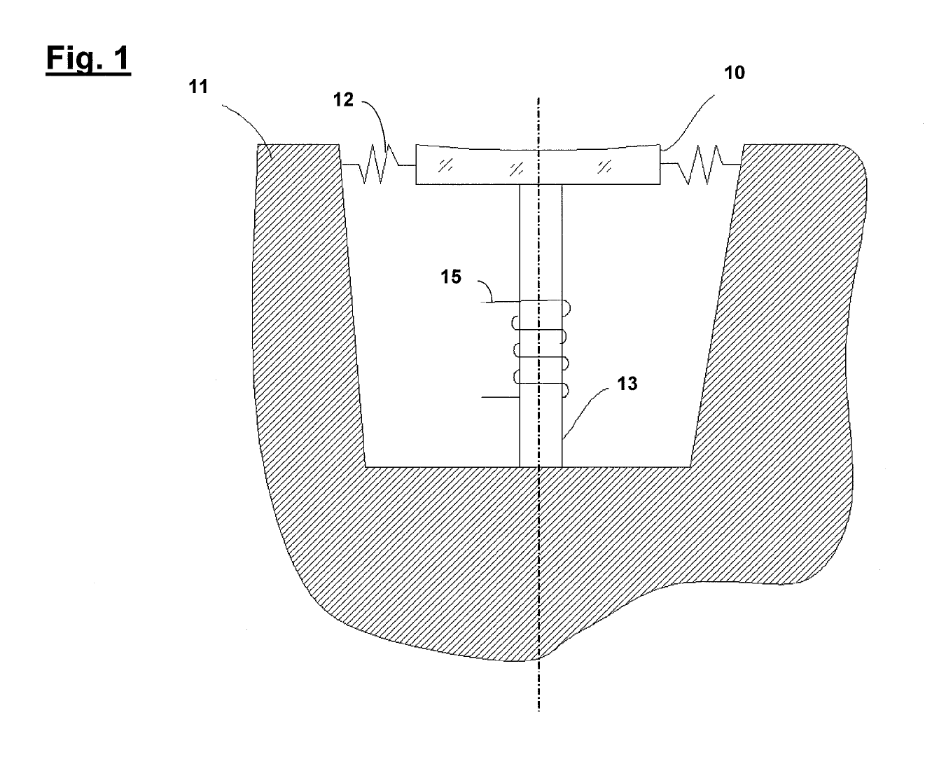

The structure of a subassembly according to the disclosure in a first embodiment of the disclosure is explained hereinafter, initially with reference to FIG. 1.

As merely schematically represented in FIG. 1, an optical element 10, which may for example be a mirror element of a mirror arrangement, such as for example a facet mirror, is coupled to a supporting structure 11 by way of a mechanical coupling 12. As described in still further detail in the further embodiments, the optical element 10 may be designed in particular to be adjustable in at least one degree of freedom (for example tiltable about at least one tilting axis).

For controlling the temperature of the optical element 10, the subassembly represented in FIG. 1 also has a temperature-controlling device in the form of a heat pipe 13, which forms a closed circuit with a tube-like portion, within which a cooling medium (not represented) can be transported away from the optical element 10 or to the optical element 10 while performing a two-phase transition (for example as already mentioned by using capillary action). In a way known per se, in a closed circuit this involves the liquid cooling medium going over into the gaseous state when heated (in the warmer end portion or in the region of the optical element 10) and changing back again into the liquid state when cooled in the colder end portion or in the region of the supporting structure 11 (or a cooler that may be present there).

The transporting of the liquid cooling medium back to the warmer end portion or the region of the optical element 10, i.e. to the location of the vaporization, may take place here for example by using capillary action.

In further embodiments, the transporting of the cooling medium may also take place by using a steady or unsteady flow as a result of a differential pressure brought about by convection between a liquid phase and a gaseous phase or else by using a liquid differential pressure brought about by convection inside a vapour chamber.

The channels serving for the flowing back and forth of the cooling medium in the liquid or gaseous phase may in principle be arranged in any geometry desired and, merely by way of example, be nested one inside the other as in the case of the heat pipe 13 or else be arranged spatially separated and at a distance from one another, as in the case of the two-phase thermosiphon that is encountered in other embodiments.

The cooling medium located within the circuit can be chosen suitably, according to the desired temperature range of the heat pipe 13, with methanol or ethanol being examples of suitable cooling media (without the disclosure being restricted to these however). A ductile (i.e. having a high long-term flexibility) and corrosion-resistant material, such as for example copper (Cu) or silver (Ag), is preferably suitable as the material of the heat pipe 13 or of the tube-like portion. In further embodiments, aluminium (Al) or high-grade steel may also be used as the material of the heat pipe 13 or of the tube-like portion. Furthermore, the heat pipe 13 may also be made up of different materials (for example a ductile material in the region of the outer wall and a mesh, for example of high-grade steel, in the region of the inner wall). Depending on the specific dimensions and depending on the cooling medium used, a ceramic material, for example including a silicon (Si)-containing material, may also be used for the heat pipe 13 or the tube-like portion.

Furthermore, the subassembly represented in FIG. 1 has an electrical heating device 15, which allows heating up of the cooling medium. Such heating up of the cooling medium can achieve the effect that the transporting of the cooling medium away from the optical element 10 or to the optical element 10 stops, so that the functionality of the heat pipe 13 is switched off, with the consequence that the optical element 10 heats up during the operation of the optical system on account of the thermal load acting. The heating device 15 that can be switched on and off means that that the heat conduction via the heat pipe 13 can therefore also be made switchable, and accordingly the temperature of the optical element 10 can be controllable in a specific manner.

For instance, merely by way of example, the temperature of the optical element 10 as a result of the electromagnetic radiation incident on the optically effective surface of the optical element 10 during the operation of the optical system may be 35° C. The switching on of the heating device 15 allows the middle region between its end portion facing the optical element 10 and its end portion facing the supporting structure 11 to be heated up to a temperature of for example 50° C. As a consequence of this, there is then no longer any outflow of heat from the optical element 10 to the supporting structure 11 (corresponding to the original thermal functionality of the heat pipe 13), but instead from the region of the heating device 15 to the supporting structure 11 (and furthermore also from the region of the heating device 15 to the optical element 10), with the consequence that the optical element 10 heats up both due to the thermal load of the incident electromagnetic radiation and due to the heat supplied by the heating device 15.

This heating up of the optical element 10 may take place for example in order to set in the region of the optically effective surface of the optical element 10 or of the mirror element the already mentioned “zero-crossing temperature”, at which no thermal expansion, or only negligible thermal expansion, of the mirror substrate material takes place, that is as long as this zero-crossing temperature exceeds the general system temperature or the temperature of the surroundings of the mirror element concerned.

In further embodiments of the disclosure, a plurality of temperature-controlling devices or heat pipes 10 may also be provided by analogy with FIG. 1, for example in a matrix-like arrangement (as an “array”). In this way, a spatially resolved temperature control can also be achieved (in order for example to achieve a thermally induced deformation of the optical element 10 that varies over the cross-sectional area of the optical element 10).

A further aspect of the subassembly that is shown in FIG. 1 is that the tubular portion forming the closed circuit is of a flexible or elastically deformable configuration. This is achieved in the exemplary embodiment by the ratio between the length and the outside diameter of the tube-like portion being at least 50:1, in particular at least 80:1. For example, the length of the tubular portion may have a value in the range of (50-100) mm, while the outside diameter may be for example 1 mm.

In embodiments, the heat pipe 13 or its tube-like portion may also have a varying cross section and/or a spiral geometry, whereby the mechanical flexibility can be increased (or the stiffness reduced), and possibly also a kinematic functionality still to be described in conjunction with the further embodiments can be assisted.

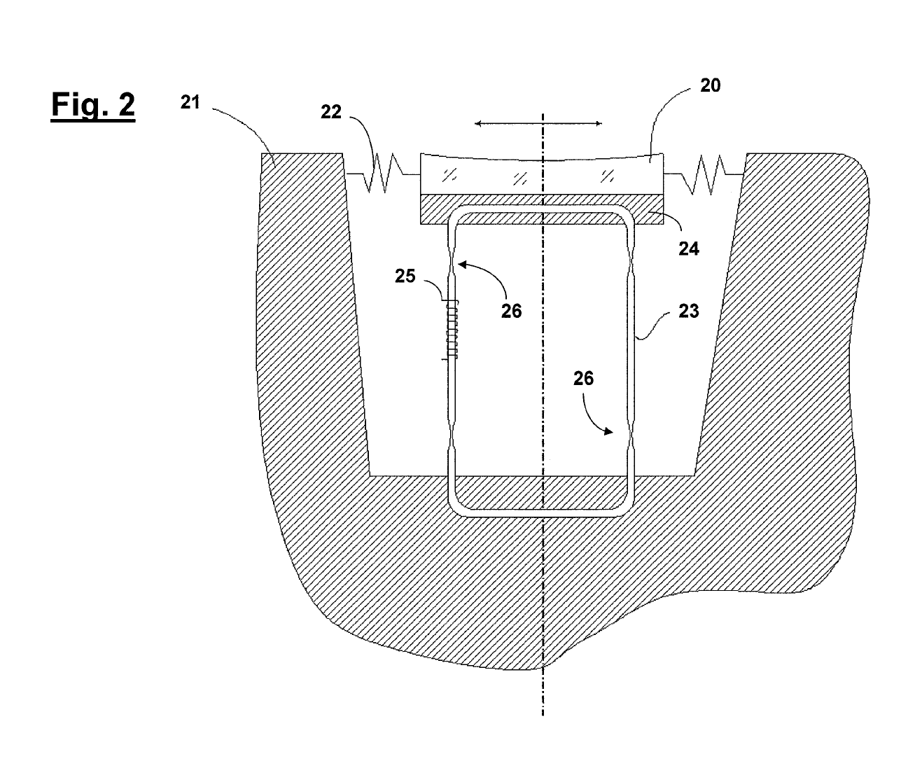

In embodiments of the disclosure, the kinematics for implementing the adjustability (for example tilting) of the optical element can be integrated into the tube-like portion that is present for the formation of the closed circuit or else be provided in addition (for example parallel) to it, as respectively explained in still more detail hereinafter on the basis of various embodiments with reference to FIG. 2-7.

FIG. 2 likewise shows in a merely schematic representation a subassembly according to the disclosure, components that are analogous or essentially functionally the same in comparison with FIG. 1 being denoted by reference numerals increased by “10”. In this case, the subassembly from FIG. 2 differs from that from FIG. 1 on the one hand in that the two-phase heat transporting system forming the temperature-controlling device is not configured as in FIG. 1 as a heat pipe but as what is known as a two-phase thermosiphon 23, parallel tubular portions that are spaced apart from one another being provided for the two-phase heat transport (one of which transports the vaporized cooling medium away from the optical element 20 and the other of which transports the liquid cooling medium to the optical element 20).

Furthermore, in the subassembly from FIG. 2, flexures 26 for implementing the adjustability of the optical element 20 in at least one degree of freedom (for example for implementing tilting about at least one tilting axis) are formed in the tube-like portion or integrated in it, in that the tube-like portion concerned is made with a reduced diameter (that is to say with a “constriction”) at the suitable points.

In the subassembly according to FIG. 2, furthermore, the temperature control of the optical element 20 does not take place directly, but instead by way of a mount or supporting structure 24 supporting the optical element 20. However, the disclosure is not restricted to this, so that, in this embodiment as in the further embodiments described, the temperature control of the optical element can take place optionally directly (such as for example according to FIG. 1) or indirectly (such as for example according to FIG. 2).

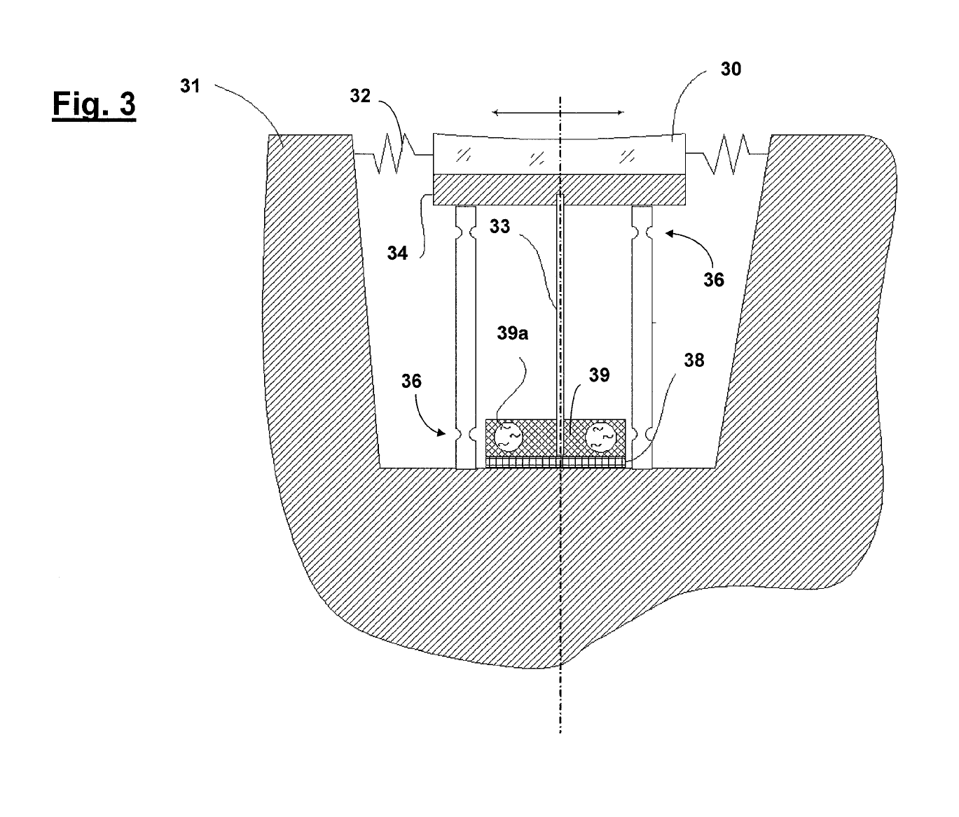

FIG. 3 shows in a schematic representation a further possible embodiment of a subassembly according to the disclosure, components that are analogous or essentially functionally the same in comparison with FIG. 2 being denoted in turn by reference numerals increased by “10”. The subassembly from FIG. 3 differs from that from FIG. 2 on the one hand in that the temperature-controlling device is in turn configured as a heat pipe 33 (to this extent by analogy with FIG. 1). Furthermore, the kinematics for implementing the adjustability (for example tiltability) of the optical element 30 are provided according to FIG. 3 by corresponding flexures 36 being configured separately from the tubular portion or the heat pipe 33 producing the circuit.

As a result of this functional separation, the kinematics (i.e. in particular the flexures 36) can thus be designed without also having to undertake at the same time the functionality of the thermal control. However, the disclosure is not restricted to this, so that the implementation of the kinematics or the formation of the flexures for this may alternatively take place here, as in the further embodiments, optionally either by being integrated in the two-phase heat transporting system ((for example heat pipe), to this extent by analogy with FIG. 2), or else separately from it (to this extent by analogy with FIG. 3).

Furthermore, according to FIG. 3, the thermal coupling of the thermal element 10 by way of the two-phase heat transporting system or the heat pipe 33 does not take place directly to the supporting structure 31, but instead to a cooler 39, which is flowed through by a cooling liquid 39a that is merely indicated in FIG. 3 and which is separated from the supporting structure 31 by a heat insulating layer 38. However, as in the further embodiments, here the thermal coupling of the optical element 30 by way of the two-phase heat transporting system may optionally take place either by way of a cooler (to this extent by analogy with FIG. 3) or else directly to the supporting structure (to this extent by analogy with FIG. 2).

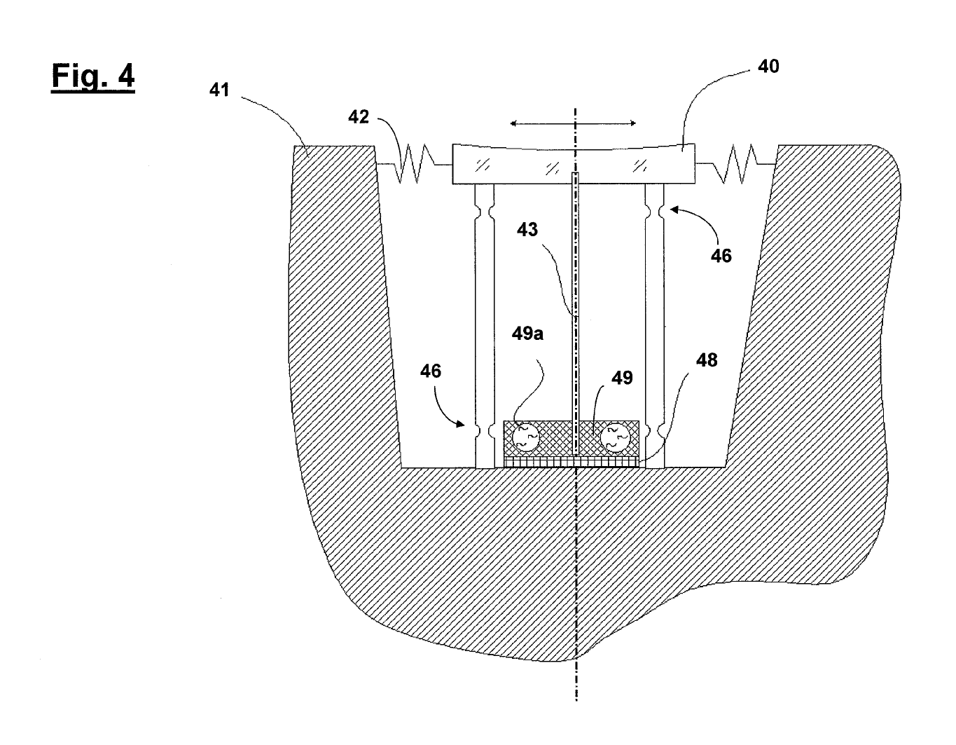

FIG. 4 shows in a schematic representation a further possible embodiment of a subassembly according to the disclosure, components that are analogous or essentially functionally the same in comparison with FIG. 3 being denoted in turn by reference numerals increased by “10”. The subassembly from FIG. 4 differs from that from FIG. 3 merely in that, according to FIG. 4, the temperature control of the optical element 40 by the heat pipe 43 does not take place as in FIG. 3 indirectly by way of a mount or supporting structure 34, but instead directly.

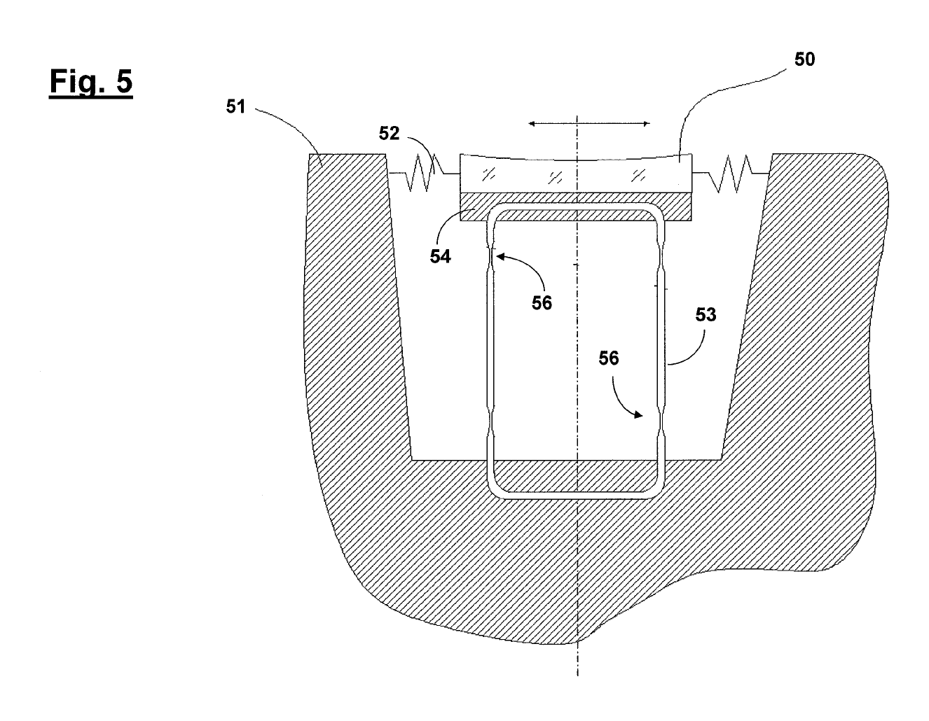

FIG. 5 shows in a schematic representation a further possible embodiment of a subassembly according to the disclosure, components that are analogous or essentially functionally the same in comparison with FIG. 4 being denoted in turn by reference numerals increased by “10”. The configuration of the subassembly according to FIG. 5 is essentially comparable to that from FIG. 2, though the heating device 25 that is present in the subassembly from FIG. 2 has been omitted.

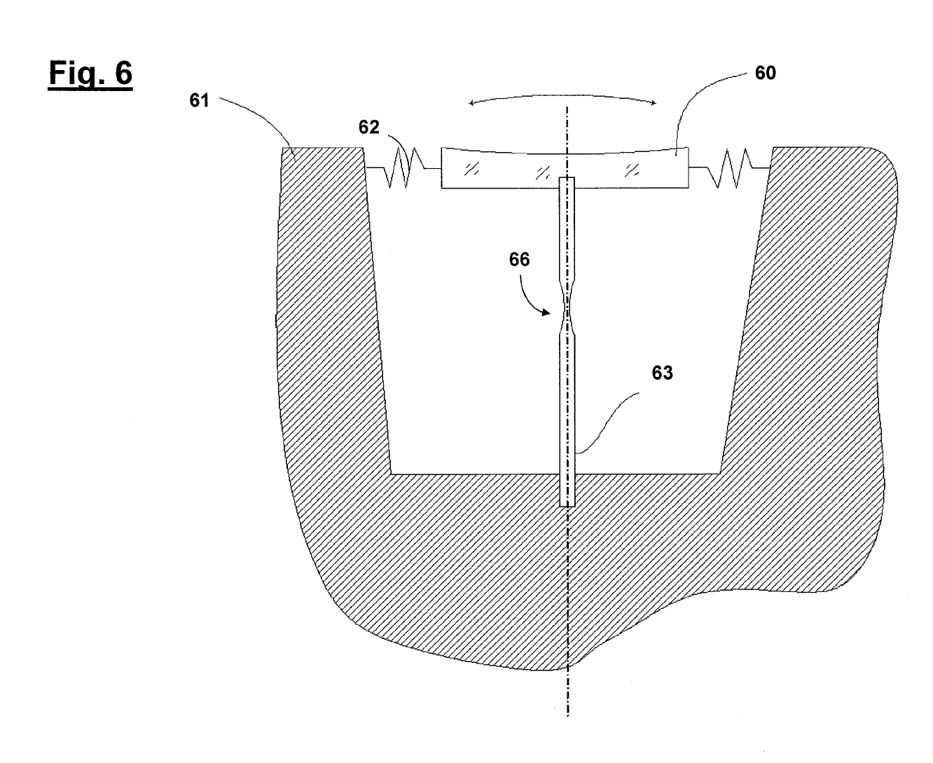

FIG. 6 shows in a schematic representation a further possible embodiment of a subassembly according to the disclosure, components that are analogous or essentially functionally the same in comparison with FIG. 5 being denoted in turn by reference numerals increased by “10”. The configuration of the subassembly from FIG. 6 differs from that from FIG. 1 on the one hand in that a flexure 66 (in the form of a constriction) is integrated in the heat pipe 63, that is to say in turn the kinematics for implementing the adjustability of the optical element 60 in at least one degree of freedom (for example the tilting about at least one tilting axis) are integrated in the tube-like portion of the temperature-controlling device that is present for the formation of the closed circuit. On the other hand, in FIG. 6 the heating device 15 present in FIG. 1, and consequently the ability to switch the heat pipe 63 on and off, has been omitted.

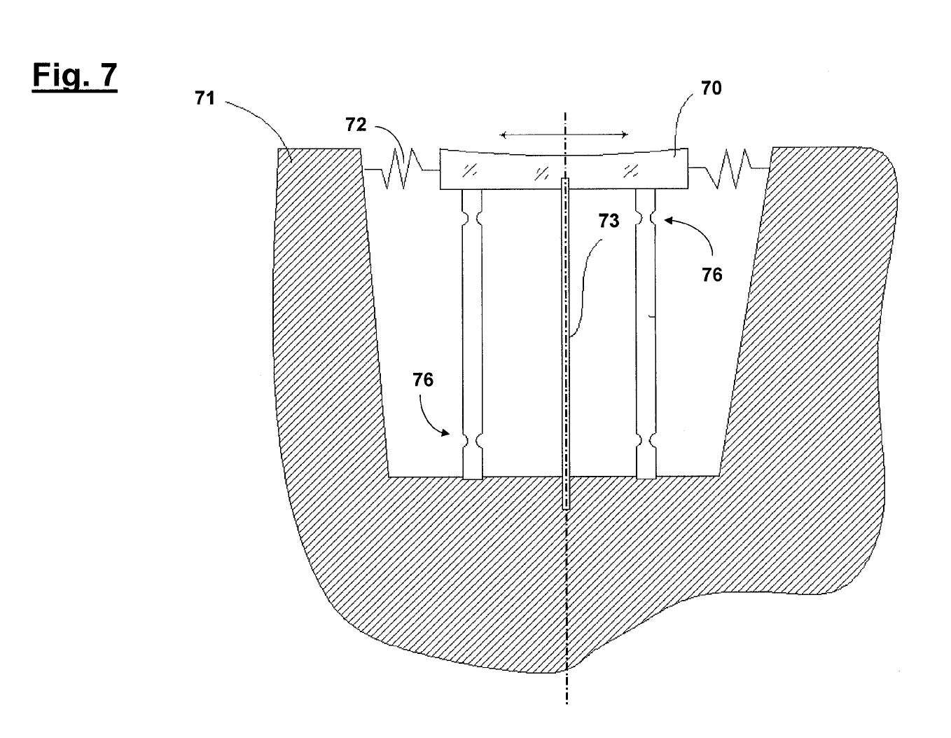

FIG. 7 shows in a schematic representation a further possible configuration of a subassembly according to the disclosure, components that are analogous or essentially functionally the same in comparison with FIG. 6 being denoted in turn by reference numerals increased by “10”. The subassembly from FIG. 7 differs from that from FIG. 6 merely in that flexures 76 for implementing the adjustability (for example tiltability) of the optical element 70 are not integrated in the heat pipe 73, but instead are provided in the form of separate kinematics.

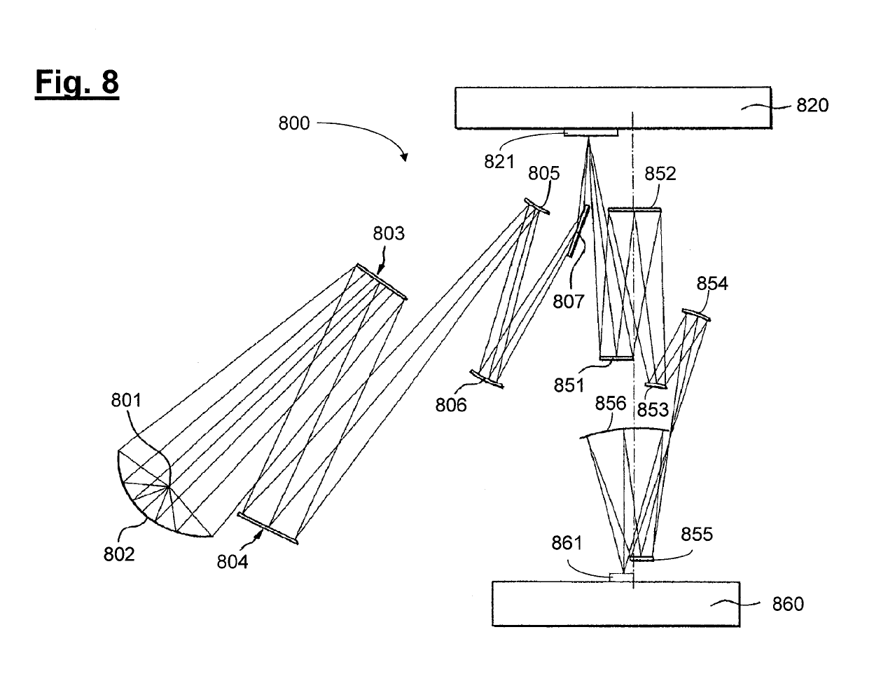

FIG. 8 shows a schematic representation of a projection exposure apparatus designed by way of example for operation in EUV, in which the present disclosure can be implemented. In further exemplary embodiments, the disclosure can also be implemented for example in an EUV light source (for instance in order to achieve a temperature control of the collector mirror present in it, which is typically likewise exposed to high thermal loads).

According to FIG. 8, in an embodiment that is merely given by way of example, an illumination device in a projection exposure apparatus 800 designed for EUV has a field facet mirror 803 and a pupil facet mirror 804. The light of a light source unit, which includes a plasma light source 801 and a collector mirror 802, is directed onto the field facet mirror 803. Arranged downstream of the pupil facet mirror 804 in the light path are a mirror 805 and a mirror 806. Arranged thereafter in the light path is a deflecting mirror 807, which directs the radiation incident on it onto an object field in the object plane of a projection lens including six mirrors 851-856. Arranged on a mask table 820 at the location of the object field is a reflective structure-bearing mask 821, an image of which is projected with the aid of the projection lens into an image plane in which a substrate 861 coated with a light-sensitive layer (photoresist) is located on a wafer table 860.

Implementation of the present disclosure in the projection exposure apparatus 800 from FIG. 8 may take place, merely by way of example, by the temperature of the individual mirror elements or mirror facets of the field facet mirror 803 or else of the pupil facet mirror 804 as optical elements being controlled in the way described in the present description. However, the disclosure is not restricted to this application and can be applied to any other desired optical elements. At the same time, application is not restricted to reflective optical elements, but instead is also possible in conjunction with any other desired optical elements (for example refractive optical elements for operation in the DUV range, for instance at wavelengths below 250 nm, in particular below 200 nm).

Even though the disclosure has been described on the basis of specific embodiments, numerous variations and alternative embodiments are evident to a person skilled in the art, for example by combining and/or exchanging features of individual embodiments. Accordingly, it goes without saying for a person skilled in the art that such variations and alternative embodiments are also covered by the present disclosure, and the scope of the disclosure is only restricted by the constraints of the accompanying patent claims and the equivalents thereof.

What is claimed is:

1. A subassembly, comprising:
an element;
a temperature-controlling device configured to control a temperature of the element; and
a heating device,
wherein:
the temperature-controlling device is configured to house a cooling medium in a closed circuit comprising a tube-like portion so that the cooling medium is transportable away from the element in the tube-like portion while performing a two-phase transition or to the element in the tube-like portion while performing a two-phase transition; and
the heating device is configured to heat the cooling medium to interrupt the transport of the cooling medium.

2. The subassembly of claim 1, wherein the heating device is an electrical heating device.

3. The subassembly of claim 1, wherein the tube-like portion is elastically deformable.

4. The subassembly of claim 1, wherein a ratio between a length of the tube-like portion to an outside diameter of the tube-like portion is at least 5:1.

5. The subassembly of claim 1, wherein the subassembly comprises a flexure configured to allow an adjustment of the element in at least one degree of freedom.

6. The subassembly of claim 1, wherein the tube-like portion comprises a flexure configured to allow an adjustment of the element in at least one degree of freedom.

7. The subassembly of claim 1, wherein the tube-like portion has a varying cross section.

8. The subassembly of claim 1, further comprising a pumping device.

9. The subassembly of claim 8, wherein the pumping device is configured to manipulate a cooling medium pressure existing within the circuit.

10. The subassembly of claim 8, wherein the pumping device is provided in a secondary circuit that is in heat exchange with the first circuit.

11. The subassembly of claim 1, wherein the temperature-controlling device is a heat pipe.

12. The subassembly of claim 1, wherein the temperature-controlling device is a two-phase thermosiphon.

13. The subassembly of claim 1, wherein the temperature-controlling device comprises a plurality of temperature-controlling devices.

14. The subassembly of claim 1, wherein the element comprises a reflective optical element.

15. The subassembly of claim 1, wherein the element comprises a collector mirror of an EUV light source.

16. The subassembly of claim 1, wherein the element comprises a microlithographic mask.

17. The subassembly of claim 1, wherein the element comprises a mirror element of a mirror arrangement which comprises a plurality of mirror elements that are adjustable independently of each other.

18. The subassembly of claim 17, wherein this mirror arrangement comprises a facet mirror.

19. The subassembly of claim 1, wherein the element is configured to operate at an operating wavelength of less than 30 nm.

20. An illumination device, comprising:
a subassembly according to claim 1,
wherein the illumination device is a microlithographic illumination device.

21. A projection lens, comprising:
a subassembly according to claim 1,
wherein the projection lens is a microlithographic projection lens.

22. An apparatus, comprising
a subassembly according to claim 1,
wherein the apparatus is a microlithographic projection exposure apparatus.

23. A method of using a microlithographic projection exposure apparatus comprising an illumination device and a projection lens, the method comprising:
using the illumination device to illuminate structures of a reticle; and
using the projection lens to project an image of at least some of the illuminated structures onto a light-sensitive material,
wherein at least one member selected from the group consisting of the illumination device and the projection lens comprises a subassembly according to claim 1.
